(19) United States
(12) Patent Application Publication
(10) Pub. No.: US 2008/0110746 A1
(43) Pub. Date: May 15, 2008

(54) Novel manufacturing design and processing methods and apparatus for sputtering targets

(76) Inventors: Janine K. Kardokus, Veradale, WA (US); Werner Hort, Cranberry, PA (US); Susan D. Strothers, Spokane, WA (US); Christie J. Hausman, Spokane, WA (US); Kevin T. Hubert, Spokane Valley, WA (US); Diana Morales, Veradale, WA (US); Michael D. Payton, Spokane, WA (US)

Correspondence Address: BUCHALTER NEMER, 18400 VON KARMAN AVE., SUITE 800, IRVINE, CA, 92612, US

(21) Appl. No.: 11/595,658

(22) Filed: Nov. 9, 2006

(51) Int. Cl. C23C 14/00

(52) U.S. Cl. 204/192.12

(57) ABSTRACT

Sputtering targets having reduced burn-in times are described herein that include: a) a machine-finished surface material having an average grain size, and b) a core material having an average grain size, wherein the machine-finished surface material has an average surface roughness (Ra) equal to or less than about the average grain size of at least one of the surface material or the core material. Sputtering targets having reduced burn-in times are described herein that include: a surface material, and a core material, wherein at least one of the surface material or the core material comprises a relatively band-free crystallographic orientation. In addition, methods of producing sputtering targets having reduced burn-in times include: providing a surface material having at least some residual surface damage, providing a core material, coupling the surface material to the core material, and machine-finishing the surface material to an average surface roughness (Ra) equal to or less than about the average grain size of at least one of the surface material or the core material. Also, methods of producing sputtering targets having reduced burn-in times include: providing a surface material combined with a core material, wherein the surface material has at least some residual surface damage and machine-finishing the surface material to an average surface roughness (Ra) equal to or less than about the average grain size of at least one of the surface material or the core material.

### FIELD OF THE INVENTION

The field of the invention is manufacturing design and processing methods and apparatus for producing sputtering targets having a decreased burn-in time.

### BACKGROUND

Electronic and semiconductor components are used in ever increasing numbers of consumer and commercial electronic products, communications products and data-exchange products. As the demand for consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, improved.

In addition to improving the quality of the layers of materials that are deposited or applied to surfaces, users also want to improve the length of time components, such as sputtering targets, can be used before their effective lifetime diminishes. In other words, users are looking to get the most out of starting materials, such as those found on a sputtering target, in order to decrease costs and maintenance time.

In a typical vapor deposition process, such as physical vapor deposition (PVD), a sample or target is bombarded with an energy source such as a plasma, laser or ion beam, until atoms are released into the surrounding atmosphere. The atoms that are released from the sputtering target travel towards the surface of a substrate (typically a silicon wafer) and coat the surface forming a thin film or layer of a material. Atoms are released from the sputtering target 10 and travel on an ion/atom path 30 towards the wafer or substrate 20, where they are deposited in a layer.

When a sputtering target is initially utilized, there is a period of time called the “burn-in time” where the surface of the target is “cleaned” of any contaminants or surface deformities in order to produce stable films on surfaces. This burn-in time is usually measured in kilowatt hours. Depending on the method of manufacturing and finishing the sputtering targets, burn-in time can be severely impacted because of surface imperfections and debris. One of the problems with a long burn-in time is that this extended time impacts productivity and overall cost of ownership of the sputtering targets.

U.S. Pat. No. 6,030,514 issued to Dunlop et al. addresses the extended burn-in time problem by utilizing non-mechanical methods to clean and polish the surface of targets before covering the target with a metal enclosure and optionally a passivating barrier layer. The metallic enclosure is designed to help reduce the burn-in time, along with the method of cleaning step. The metallic enclosure or metal layer is an additional step in the process, which can add cost and production time to the product.

US Patent Publication 2005/0040030 also discusses reducing the burn-in time of a target by dry treating the sputtering target using a sputtering ion plasma, however, this publication reduces the burn-in time of the target in a vacuum chamber, as opposed to pretreating the surface material. The utilization of a vacuum chamber can add costs and maintenance time to the production of the target.

To this end, it would be desirable to produce a sputtering target that a) can be produced with a minimal amount of residual surface damage, b) can be produced to minimize burn-in times by at least 25% as compared to conventional sputtering targets, c) can be produced to minimize surface and near surface distortions of the crystallographic orientation, d) can be produced with a uniform, band-free crystallographic orientation, and e) can be produced efficiently.

### SUMMARY OF THE INVENTION

Sputtering targets having reduced burn-in times are described herein that include: a) a machine-finished surface material having an average grain size, and b) a core material having an average grain size, wherein the machine-finished surface material has an average surface roughness (Ra) equal to or less than about the average grain size of at least one of the surface material or the core material.

Sputtering targets having reduced burn-in times are described herein that include: a surface material, and a core material, wherein at least one of the surface material or the core material comprises a relatively band-free crystallographic orientation.

In addition, methods of producing sputtering targets having reduced burn-in times include: providing a surface material having at least some residual surface damage, providing a core material, coupling the surface material to the core material, and machine-finishing the surface material to an average, surface roughness (Ra) equal to or less than about the average grain size of at least one of the surface material or the core material. Also, methods of producing sputtering targets having reduced burn-in times include: providing a surface material combined with a core material, wherein the surface material has at least some residual surface damage and machine-finishing the surface material to an average surface roughness (Ra) equal to or less than about the average grain size of at least one of the surface material or the core material.

In determining the residual surface damage, methods have been developed that include: providing a sputtering target having a surface, wherein the surface comprises a plurality of crystal grains and wherein each crystal grain has a crystal orientation, providing an electron beam, scanning the surface with the electron beam, collecting data from the electron beam scanning, wherein the data provides a local variation in a crystal orientation of each crystal grain; and utilizing the data to determine the thickness of the surface layer and the degree of residual surface damage.

### BRIEF DESCRIPTION OF THE FIGURES

FIGS. 1A and 1B show the schematic of an as-machined surface and of a polished surface with a residual surface damage layer.

FIG. 2 shows a graph with “I-V” curves, where operating current (A) and operating voltage (V) are represented on the graph.

FIG. 3 shows a bar graph of tantalum film reflectivity data, specifically reflectivity at 480 nm for each of the three targets over 5 kW-hours, 10 kW-hours and 20 kW-hours.

### DESCRIPTION OF THE SUBJECT MATTER

A sputtering target has been produced that a) can be produced with a minimal amount of residual surface damage, b) can be produced to minimize burn-in times by at least 25% as compared to conventional sputtering targets, c) can be produced to minimize surface and near surface distortions of the crystallographic orientation, d) can be produced with a uniform, band-free crystallographic orientation, and e) can be produced efficiently. In addition, methods and apparatus have been discovered that can successfully identify the thickness of the surface layer and the degree of residual surface damage and in turn help to understand the impact of this residual surface damage on the burn-in time of the target.

Sputtering targets and sputtering target assemblies contemplated and produced herein comprise any suitable shape and size depending on the application and instrumentation used in the vapor deposition processes. Sputtering targets contemplated and produced herein comprise a surface material having an average grain size and a core material (which includes the backing plate) having an average grain size. The surface material and core material may generally comprise the same elemental makeup or chemical composition/component, or the elemental makeup and chemical composition of the surface material may be altered or modified to be different than that of the core material. However, in embodiments where it may be important to detect when the target's useful life has ended or where it is important to deposit a mixed layer of materials, the surface material and the core material may be tailored to comprise a different elemental makeup or chemical composition.

Sputtering targets having reduced burn-in times are described herein that include: a) a machine-finished surface material having an average grain size, and b) a core material having an average grain size, wherein the machine-finished surface material has an average surface roughness (Ra) equal to or less than about the average grain size of at least one of the surface material or the core material.

The surface material is that portion of the target that is intended to produce atoms and/or molecules that are deposited via vapor deposition to form the surface coating/thin film. This surface material is important because it is this layer of material that directly affects burn-in time, as discussed earlier. Conventional sputtering targets are generally manufactured and finished by sanding or buffing the surface material, and while this process produces a uniform and attractive surface appearance, the process leaves behind a relatively significant amount of residual surface damage and surface particulate/debris. In contemplated embodiments, as discussed herein, sputtering targets are instead machine-finished in order to produce a surface material with a lower incidence of residual surface damage. In other embodiments, sputtering targets are machine-finished to produce a surface material with quantitatively little to no residual surface damage. In some embodiments, the machine finishing is accomplished using a carbide insert. In other embodiments, the surface material is machined utilizing electrostatic discharge machining (EDM), electrochemical machining (ECM) or a sequence or combination of these processes, including the carbide insert.

Electrical discharge machining (or EDM) is a machining method primarily used for hard metals or those that would be impossible to machine with traditional techniques. One critical limitation, however, is that EDM only works with materials that are electrically conductive. EDM can cut small or odd-shaped angles, intricate contours or cavities in extremely hard steel and exotic metals such as titanium, hastelloy, kovar, inconel and carbide. Sometimes referred to as spark machining or spark eroding, EDM is a nontraditional method of removing material by a series of rapidly recurring electric arcing discharges between an electrode (the cutting tool) and the work piece, in the presence of an energetic electric field. The EDM cutting tool is guided along the desired path very close to the work but it does not touch the piece. Consecutive sparks produce a series of micro-craters on the work piece and remove material along the cutting path by melting and vaporization. The particles are washed away by the continuously flushing dielectric fluid. There are two main types of EDM machines, ram and wire-cut. (see: http://en.wikipedia.org/wiki/Electrical discharge machining).

Electrochemical machining (ECM) is based on a controlled anodic electrochemical dissolution process of the workpiece (anode) with the tool (cathode) in an electrolytic cell, during an electrolysis process. Electrochemical Machining (ECM) is similar to electropolishing in that it also is an electrochemical anodic dissolution process in which a direct current with high density and low voltage is passed between a workpiece and a preshaped tool (the cathode). At the anodic workpiece surface, metal is dissolved into metallic ions by the deplating reaction, and thus the tool shape is copied into the workpiece. (see: http://www.unl.edu/nmrc/ECMoutline.htm)

The phrase “residual surface damage” as used herein refers to that portion of a sputtering target that does not contain material or material configurations that are suitable for desirable sputtered layers. For example, in some embodiments, residual surface damage may be the presence of layers or pockets of crystal grains that are “misoriented” or not oriented in such as fashion as to properly direct sputtered atoms. For example, there may be surface or near surface distortion of the crystallographic lattice. In other embodiments, residual surface damage may be the presence of layers or pockets of debris, particulate or other materials that are not considered to be suitable sputterable material, such as sand, dust, grit or other materials. In yet other embodiments, residual surface damage may be the presence of layers or pockets of uneven terrain on the sputtering target. This embodiment is different from misoriented crystal grains, in that there are portions of the sputtering target itself that are damaged beyond just misoriented crystal grains, and this damage is more significant than misoriented crystal grains. In other embodiments, residual surface damage refers to a combination of two or more of the above. It should be obvious, however, that the degree of residual surface damage can directly impact the burn-in time of the target or the time it takes before the target becomes useful for sputtering acceptable layers of materials on a surface.

As mentioned, it has been discovered that surface roughness is a component of residual surface damage and has a direct correlation to the burn-in times for a sputtering target. Therefore, it is important to ensure that the surface roughness is minimized for all types of targets. Some targets, such as tantalum, present problems when trying to minimize surface roughness. A conventional sanding or buffing process is used to remove surface roughness, and while it is successful in producing a uniform product, it leaves particulate or debris deposition on the target—another contributor to residual surface damage and slow burn-in times. Therefore, in contemplated embodiments, the surface material is machine-finished—meaning that the surface is machined with a suitable tool to remove roughness without leaving behind deposits, particulates or debris. In some embodiments, a carbide insert is used to machine-finish the surface material. In other embodiments, the surface material is machined utilizing electrostatic discharge machining (EDM), electrochemical machining (ECM) or a sequence or combination of these processes, including the carbide insert.

In contemplated embodiments, as mentioned, average surface roughness (Ra) should be equal to or lower than about the average grain size of the bulk material. In some embodiments, contemplated machine-finished surface materials comprise less than about 64 microinches surface roughness (Ra). In other embodiments, contemplated surface materials comprise less than about 32 microinches surface roughness (Ra). In yet other embodiments, contemplated surface materials comprise less than about 16 microinches surface roughness (Ra).

Crystallographic orientation of the surface material, core material or a combination thereof is also important to the operation of the sputtering target and to the reduction of burn-in times. Specifically, crystallographic orientation of the materials in the sputtering target is particularly important in those materials where sputter rate/deposition rate is strongly dependent on crystallographic orientation of the grains. One of these materials is tantalum. In contemplated sputtering targets, the target can be produced to minimize surface and near surface distortions of the crystallographic orientation and/or can be produced with a uniform, band-free crystallographic orientation. Sputtering targets having reduced burn-in times are described herein that include: a surface material, and a core material, wherein at least one of the surface material or the core material comprises a relatively band-free crystallographic orientation. It should be understood that it is not necessary to have a machine-finished surface for these targets having a relatively band-free crystallographic orientation, especially since this band-free orientation results in a reduced burn-in time for the final sputtering target.

The first mechanism addresses surface and near surface distortions, which affect every target in this class, regardless of the PVD tool design, target configuration or PVD process. The second mechanism (band-free orientation) deals with variations in crystallographic orientation below the surface of the target. In this case, bands of grains with strong preferred orientation can cause shifts in deposition rate, as the sputtering process uncovers different bands. Depending on the design of the PVD tool, the target configuration and the particular process that is being utilized. It is possible to simultaneously uncover multiple bands, resulting in a phenomenon that presents itself as an unusually long burn-in time. PVD tools that use magnets that strongly focus the magnetic field in a highly localized region, resulting in a deep erosion groove, are highly susceptible to this mechanism of deposition rate variation.

The first issue is to fabricate a texture band-free blank to be used in the production of the final sputtering target. This blank is produced by utilizing plasma spray, cold spray or a similar spray technique onto a target form or backing plate. In some embodiments, the form or backing plate can be “shape-matched” to mimic the erosion profile in order to minimize material usage. Powder metallurgy may also be used where HIP or vacuum hot press with TaH₂ or, in some embodiments, TiH₂ powder is applied to the top and bottom of a layer of tantalum powder in a die, such as a graphite die. The TaH₂ or TiH₂ powder draws oxygen away from the tantalum, thus deoxidizing tantalum and acting as an “oxygen scavenger” for any oxygen that is released from tantalum. One or both titanium layers can be removed later before the tantalum is bond-assembled, or one or both of the titanium layers can be utilized as interlayers to facilitate bonding. In other embodiments, a material, such as copper, can be utilized to planarize tantalum bonding surfaces to simplify diffusion bonding. This layer can be applied via plasma spray, cold spray or another suitable spray technique. The planarizing layer is then lowered into a backing plate fitted with an opening to accept the assembly. The planarization layer is then e-beam welded to the backing plate and the whole assembly is pressed to bond, such as by HIP.

Once the texture band-free target blank is formed, it can be bond-assembled by any suitable methods and then machined to form a defect-free surface, as contemplated and described herein. Targets formed using these texture band-free target blanks obviously show an absence of texture bands and comprise a more uniform crystallographic orientation.

In addition, contemplated sputtering targets may be annealed to further reduce any residual surface damage. Surface stresses may also be removed by utilizing a thermal treatment, such as laser treatment, e-beam treatment, thermal treatment or plasma spray treatment, heat contact treatment, etc. When utilizing both at least one annealing step and at least one thermal treatment step, the goal is to anneal out the residual surface damage and create a recrystallized layer that is defect free. Examples of thermal treatments include e-beam, laser treatment, thermal spray, plasma spray, explosive flash treatments, etc.

Sputtering targets contemplated herein may generally comprise any material that can be a) reliably formed into a sputtering target; b) sputtered from the target when bombarded by an energy source; and c) suitable for forming a final or precursor layer on a wafer or surface. Materials that are contemplated to make suitable sputtering targets are metals, metal alloys, conductive polymers, conductive composite materials, dielectric materials, hardmask materials and any other suitable sputtering material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, ruthenium or a combination thereof. More preferred metals include copper, aluminum, tungsten, titanium, cobalt, tantalum, magnesium, lithium, silicon, manganese, iron or a combination thereof. Most preferred metals include copper, aluminum and aluminum-based materials, tungsten, titanium, zirconium, cobalt, tantalum, niobium, ruthenium or a combination thereof. Examples of contemplated and preferred materials, include aluminum and copper for superfine grained aluminum and copper sputtering targets; aluminum, copper, cobalt, tantalum, zirconium, and titanium for use in 200 mm and 300 mm sputtering targets, along with other mm-sized targets; and aluminum for use in aluminum sputtering targets that deposit a thin, high conformal “seed” layer or “blanket” layer of aluminum surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term ” metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, ruthenium, tantalum, tin, zinc, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium, tantalum ruthenium, copper manganese, germanium antimony telluride, copper gallium, indium selenide, copper indium selenide and copper indium gallium selenide and/or combinations thereof.

As far as other materials that are contemplated herein for sputtering targets, the following combinations are considered examples of contemplated sputtering targets (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof. In some embodiments, contemplated materials include those materials disclosed in U.S. Pat. No. 6,331,233, which is commonly-owned by Honeywell International Inc., and which is incorporated herein in its entirety by reference.

In addition, methods of producing sputtering targets having reduced burn-in times include: providing a surface material having at least some residual surface damage, providing a core material, coupling the surface material to the core material, and machine-finishing the surface material to an average surface roughness (Ra) equal to or less than about the average grain size of at least one of the surface material or the core material. Also, methods of producing sputtering targets having reduced burn-in times include: providing a surface material combined with a core material, wherein the surface material has at least some residual surface damage and machine-finishing the surface material to an average surface roughness (Ra) equal to or less than about the average grain size of at least one of the surface material or the core material. In both of these methods, it should be clear that either the target is produced with a surface material that blends in with the core material to produce a target, or the target is produced with a surface material that is coupled to the core material to produce a target.

In determining the residual surface damage, methods have been developed that include: providing a sputtering target having a surface, wherein the surface comprises a plurality of crystal grains and wherein each crystal grain has a crystal orientation, providing an electron beam, scanning the surface with the electron beam, collecting data from the electron beam scanning, wherein the data provides a local variation in a crystal orientation of each crystal grain; and utilizing the data to determine the thickness of the surface layer and the degree of residual surface damage.

One of the techniques utilized in contemplated methods of determining residual surface damage is Electron Backscatter Diffraction (EBSD), which is a technique which allows crystallographic information to be obtained from samples in the scanning electron microscope (SEM). In EBSD, a stationary electron beam strikes a tilted crystalline sample and the diffracted electrons form a pattern on a fluorescent screen. This pattern is characteristic of the crystal structure and orientation of the sample region from which it was generated. The diffraction pattern can be used to measure the crystal orientation, measure grain boundary misorientations, discriminate between different materials, and provide information about local crystalline perfection. When the beam is scanned in a grid across a polycrystalline sample and the crystal orientation measured at each point, the resulting map will reveal the constituent grain morphology, orientations, and boundaries. This data can also be used to show the preferred crystal orientations (texture) present in the material. A complete and quantitative representation of the sample microstructure can be established with EBSD. (see HTTP://WWW.EBSD.COM/EBSDEXPLAINED.HTM)

One can measure crystal imperfection with various X-ray techniques, however, these techniques are neither straight forward to implement nor to interpret. Additionally, with X-ray a majority of the information comes from a very thin surface layer. The signal decays exponentially with depth. In the case of Ta and the most common Cu K-alpha radiation, 95% of the signal comes from a depth of less than 5 micron. In addition to that, the information gathered by X-ray diffraction is of a macroscopic nature. It is averaged over all the grains illuminated by the beam. With EBSD, one gets grain by grain information of the state of local misorientation. If the crystal imperfections are localized, such as under the machining grooves, it would affect sputtering and it would show up with the EBSD technique.

### EXAMPLES

### Example 1

### Tantalum Target Burn-In Reduction Study

As discussed herein, a brand new sputtering target without a period of burn-in time will produce several defects and inconsistencies in performance and film quality, including inconsistent film resistivity (deposition rate, thickness, etc.), more particles, lower film reflectivity and generally inconsistent target and film performance. These defects and inconsistencies are generally caused by: a) the surface material of the target is not the same as the bulk material, b) techniques used to create the final finished surface can damage the surface of the material, as discussed earlier, including highly dislocated or twinned material, smeared surface material and/or oxidized or contaminated material at the surface.

Reflectivity of a metal surface depends not only on the micro-topography, but also the electrical conductivity of the surface. Polished surfaces produce inferior reflectivity because of surface damage that also decreases electrical resistivity. Micro-machined surfaces, produced by single-point diamond turning for example, resulted in superior reflectivity over polished surfaces. (see “Performance Characteristics of Single Point Diamond Machined Metal Mirrors for Infrared Laser Applications”, T. T. Saito and L. B. Simmons, Applied Optics, November 1974, Volume 13, Number 11, pages 2647-2650).

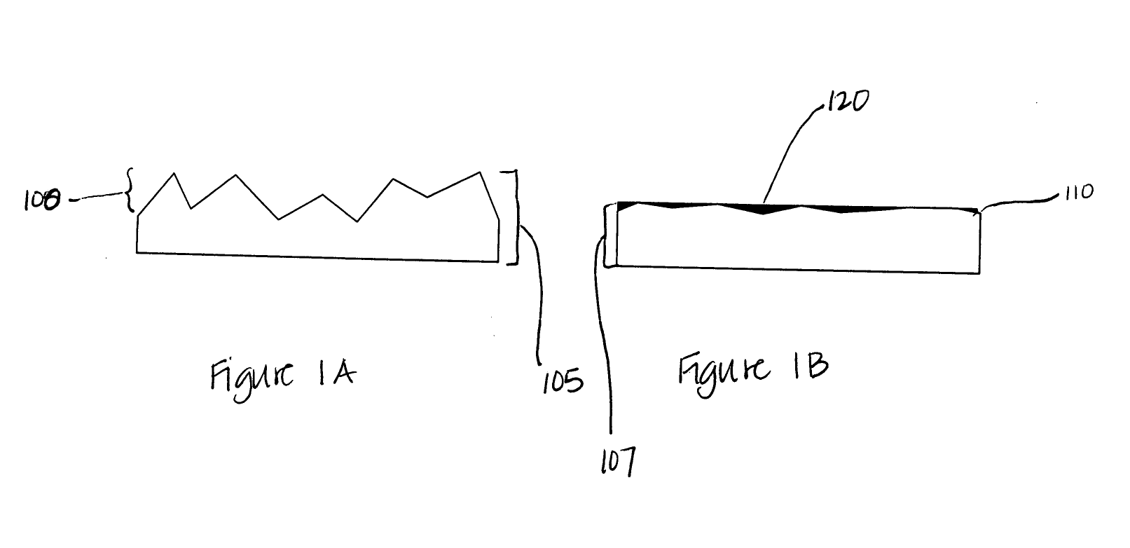

Tantalum is not an easy material to machine to a fine finish. Heat builds up easily between the machining tool and tantalum, even with flood cooling. The result is microscopic tear-outs that create a rough-looking surface, even when the overall surface finish is less than about 16 microinches surface roughness (Ra). The conventional approach to dealing with the surface finish is to sand or polish the tantalum surface to improve the visual appearance. And although polishing makes the surface smooth, a damaged layer or residual surface damage develops. This residual surface damage layer, as discussed, extends burn-in time for a sputtering target. FIGS. 1A and 1B show the schematic of an as-machined surface (100) of a sputtering target (105) and of a polished surface (110) of a sputtering target (107) with a residual surface damage layer (120).

The current study compared a standard finish tantalum target (7 Ra, standard polished finish) that was finished with sanding and polishing with two different as-machined target finishes (16 Ra, as-machined to 16 finish, and 27 Ra, as machined to 32 finish). Since burn-in is highly subject to individual customer requirements, film reflectivity was used to determine whether the target was fully burned in. Low reflectivity indicates the presence of residual oxides and contaminant pockets or layers. In addition, normal reflectivity indicates that the damaged layer has burned off and that the exposed portion of the target comprises an undamaged layer.

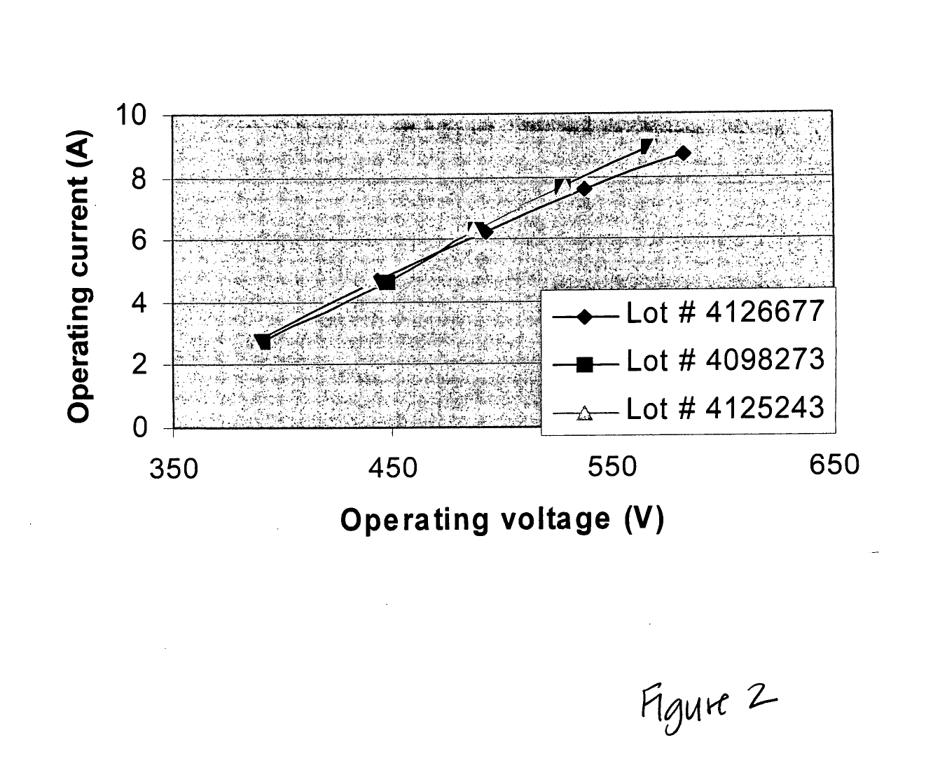

FIG. 2 shows a graph with “I-V” curves, where operating current (A) and operating voltage (V) are represented on the graph. The targets with as-machined 16 Ra (Lot 4098273) and 27 Ra (Lot 4125243) show virtually identical I-V curves. The target with polished 7 Ra standard finish (Lot 4126677) operated at a slightly higher voltage, potentially because of the residual resistive damage layer.

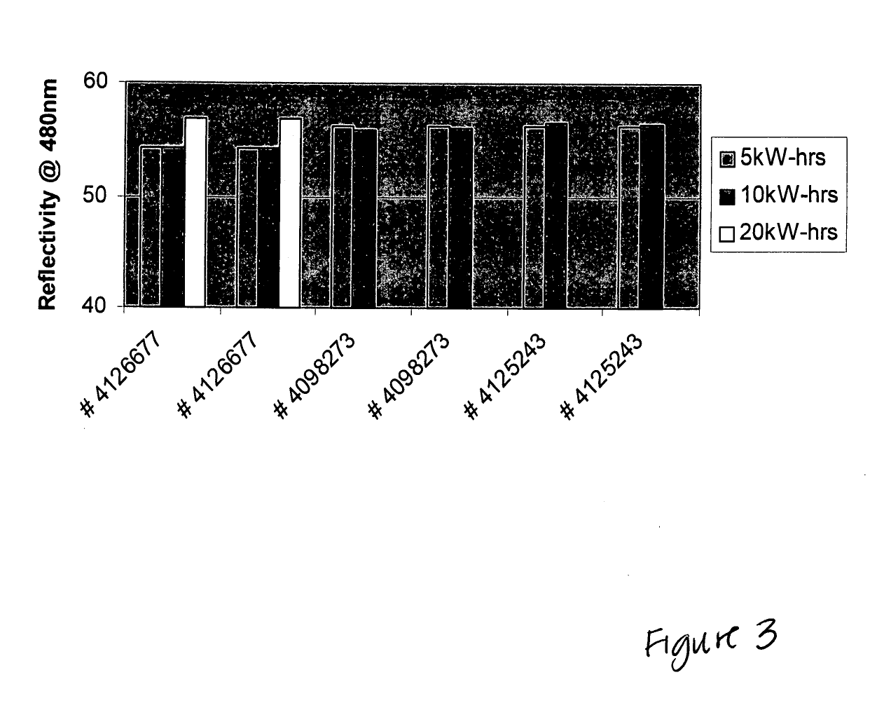

FIG. 3 shows a bar graph of tantalum film reflectivity data, specifically reflectivity at 480 nm for each of the three targets mentioned above over 5 kW-hours, 10 kW-hours and 20 kW-hours. The film reflectivity of the standard finish polished target (7 Ra) was initially lower than those of the as-machined targets. The reflectivity of the polished standard target recovered after about 4 times longer burn-in or 20 kW-hours. The as-machined surfaces appear to have less of a residual surface damage layer.

### Example 2

### Experimental Procedure and Typical Results

### Sample Preparation:

Cross sections of the sputtering target material perpendicular to the surface are prepared in order to be analyzed. It was found to be advantageous to start by making two parallel cuts with a precision saw such as the Struers Accutom. This enables one to mount the sample with adhesive tape to regular SEM mounts while ensuring that the surface of interest stays parallel to the focusing plane of the microscope. Cutting speeds typically vary from 0.005 to 0.02 mm/sec. In most embodiments, the slower speed will be used for the surface that will be analyzed. This reduction in speed minimizes the amount of damage that the cutting process can introduce. The length of the cut is typically 10-25 mm. The sample is then mounted in conductive resin, ground to 4000 grit and then polished to 3 micron. Finally the sample is electro-polished in an 80/20 sulfuric/HF solution.

At this point, the sample is broken out of the resin mount and it is attached with conductive tape to the SEM mount. Alternate preparation techniques forego the two parallel cuts and use the conductive resin mount directly in the SEM. In this case, the geometric features of the conductive resin mount ensure the alignment of the investigated surface in the electron microscope. However, the samples have a tendency towards edge rounding during the polishing process. This results in the sample surface to be lower than the mounting material. This causes the diffracted electron beam from points close to the surface to be intercepted by the mount. This is not a big problem if one is interested in bulk properties. However, it compromises the data from the region of interest for a surface analysis.

The data collection part is basically the same as for any other EBSD study. The sample is tilted to about 70 degree, the diffracted electrons are intercepted by a phosphor screen/detector. A low light camera records the image, the image is enhanced and then processed by a computer to determine the orientation of the crystalline region that is interacting with the electron beam. Since the distribution of crystal orientation within the grains is the important factor, it is advisable to use mapping grid that is a fraction of the expected grain size. Typical tantalum material that has been analyzed has an average grain size of about 50-60 micron, however, many grains will be considerably smaller than that. Grid spacing of 2-5 micron has successfully been used for this material. Data is then collected according to the expected depth of the deformation layer and a width that will depend on the machining groove pattern. Typically 80-100 micron by 2-3 mm.

The data is then analyzed by calculating the average variation of crystalline orientation. Commercial software packages (for example, Channel from—HKL Technology) provide map components that do these calculations. Basically, for each point within a grain, the software calculates the angular difference in orientation for this point and its neighboring points (as long as they are in the same grain) and then averages the value. Multiple schemes can be set up that use either only nearest neighbors or nearest and next nearest neighbors or even more points. The exact scheme is not of importance. The more localized version is preferred, as they provide better spatial resolution. The resulting data is then plotted and the burn-in affecting layer is identified by locating the depth at which the data starts deviating from the bulk value.

Thus, specific embodiments and applications of methods of manufacturing sputtering targets and related apparatus have been disclosed. It should be apparent, however, to those skilled in the art that many more modifications besides those already described are possible without departing from the inventive concepts herein. The inventive subject matter, therefore, is not to be restricted except in the spirit of the disclosure and claims herein. Moreover, in interpreting the disclosure and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A sputtering target having reduced burn-in times, comprising:
a machine-finished surface material having an average grain size, and
a core material having an average grain size, wherein the machine-finished surface material has an average surface roughness (Ra) equal to or less than about the average grain size of at least one of the surface material or the core material.

2. The sputtering target of claim 1, wherein the burn-in time is reduced by at least 50% over a conventional sputtering target comprising a non-machine-finished surface material.

3. The sputtering target of claim 2, wherein the burn-in time is reduced by at least 75% over a conventional sputtering target comprising a non-machine-finished surface material.

4. The sputtering target of claim 1, wherein the average surface roughness is less than about 64 microinches.

5. The sputtering target of claim 4, wherein the average surface roughness is less than about 32 microinches.

6. The sputtering target of claim 1, wherein the surface material comprises at least one refractory metal.

7. The sputtering target of claim 6, wherein the at least one refractory metal comprises tantalum, titanium, tungsten, molybdenum, cobalt, nickel or combinations thereof.

8. The sputtering target of claim 1, wherein the surface material and the core material comprise the same materials.

9. The sputtering target of claim 1, wherein at least one of the surface material or the core material comprises a relatively band-free crystallographic orientation

10. A sputtering target having reduced burn-in times, comprising:
a surface material, and
a core material, wherein at least one of the surface material or the core material comprises a relatively band-free crystallographic orientation.

11. A method of producing a sputtering target having reduced burn-in times, comprising:
providing a surface material having at least some residual surface damage and having an average grain size,
providing a core material having an average grain size,
coupling the surface material to the core material, and
machine-finishing the surface material to an average surface roughness (Ra) equal to or less than about the average grain size of at least one of the surface material or the core material.

12. A method of producing a sputtering target having reduced burn-in times, comprising:
providing a surface material having an average grain size combined with a core material having an average grain size, wherein the surface material has at least some residual surface damage, and
machine-finishing the surface material to an average surface roughness (Ra) equal to or less than about the average grain size of at least one of the surface material or the core material.

13. The method of one of claims 11 or 12, wherein machine-finishing the surface material comprises utilizing a carbide insert to machine finish the surface material.

14. The method of one of claims 11 or 12, wherein machine-finishing the surface material comprises utilizing electrostatic discharge machining (EDM), electrochemical machining (ECM) or a combination thereof.

15. The method of one of claims 11 or 12, further comprising annealing the surface material to reduce the residual surface damage.

16. The method of one of claims 11 or 12, further comprising annealing the surface material to reduce the residual surface damage and thermally treating the surface material to recrystallize the surface material.

17. The method of one of claims 11 or 12, wherein the burn-in time is reduced by at least 50% over a conventional sputtering target comprising a non-machine-finished surface material.

18. The method of one of claims 11 or 12, wherein the average surface roughness is less than about 64 microinches.

19. The method of one of claims 11 or 12, wherein the average surface roughness is less than about 32 microinches.

20. The method of one of claims 11 or 12, wherein the surface material comprises at least one refractory metal.

21. The method of one of claims 11 or 12, wherein the at least one refractory metal comprises tantalum, titanium, tungsten, molybdenum, cobalt, nickel or combinations thereof.

22. The method of one of claims 11 or 12, wherein the burn-in time is reduced by at least 50% over a conventional sputtering target comprising a non-machine-finished surface material.

23. The method of one of claims 11 or 12, wherein the burn-in time is reduced by at least 75% over a conventional sputtering target comprising a non-machine-finished surface material.

24. A method of determining the degree of residual surface damage, comprising:
providing a sputtering target having a surface, wherein the surface comprises a plurality of crystal grains and wherein each crystal grain has a crystal orientation,
providing an electron beam,
scanning the surface with the electron beam,
collecting data from the electron beam scanning, wherein the data provides a local variation in a crystal orientation of each crystal grain; and
utilizing the data to determine the thickness of the surface layer and the degree of residual surface damage.

25. The method of claim 24, wherein the degree of residual surface damage is directly related to the burn-in time of the sputtering target.
